(19) United States
(12) Patent Application Publication
(10) Pub. No.: US 2024/0243694 A1
(43) Pub. Date: Jul. 18, 2024

(54) Enhanced Flexible Solar Panels and Photovoltaic Devices, and Methods and Systems for Producing Them

(71) Applicant: SOLARPAINT LTD., YOKNEAM ILLIT (IL)

(72) Inventors: Eran Maimon, Kibbutz Nahsholim (IL); Omri Gover, Tel Aviv (IL); Yaron Tidhar, Even Yehuda (IL); Haggai Manor, Beit Lehem HaGlilit (IL); Hod Yarkoni, Tel Aviv (IL); Ramon Joseph Albalak, Haifa (IL)

(21) Appl. No.: 18/586,478

(22) Filed: Feb. 25, 2024

Related U.S. Application Data
(63) Continuation of application No. PCT/IL2022/050934, filed on Aug. 29, 2022.
(63) Continuation-in-part of application No. 18/129,865, filed on Apr. 2, 2023.
Application No. 18/129,865 is a continuation of application No. PCT/IL2021/051202, filed on Oct. 7, 2021.
Application No. PCT/IL2021/051202 is a continuation-in-part of application No. 17/353,867, filed on Jun. 22, 2021, now Pat. No. 11,978,815.
Application No. 18/129,865 is a continuation-in-part of application No. 17/353,867, filed on Jun. 22, 2021, now Pat. No. 11,978,815.
(63) Continuation-in-part of application No. 17/353,867, filed on Jun. 22, 2021, now Pat. No. 11,978,815.
Application No. 17/353,867 is a continuation-in-part of application No. 16/362,665, filed on Mar. 24, 2019, now Pat. No. 11,081,606.
Application No. 17/353,867 is a continuation-in-part of application No. PCT/IL2019/051416, filed on Dec. 26, 2019.
Application No. PCT/IL2019/051416 is a continuation-in-part of application No. 16/362,665, filed on Mar. 24, 2019, now Pat. No. 11,081,606.
Application No. 18/129,865 is a continuation-in-part of application No. 17/802,335, filed on Aug. 25, 2022.
(63) Continuation-in-part of application No. 18/372,720, filed on Sep. 26, 2023.
Application No. 18/372,720 is a continuation of application No. PCT/IL2022/050339, filed on Mar. 29, 2022.
Application No. PCT/IL2022/050339 is a continuation-in-part of application No. PCT/IL2021/051202, filed on Oct. 8, 2021.
Application No. PCT/IL2021/051202 is a continuation-in-part of application No. PCT/IL2021/051269, filed on Oct. 27, 2021.
Application No. PCT/IL2021/051269 is a continuation-in-part of application No. PCT/IL2022/050030, filed on Jan. 10, 2022.
Application No. PCT/IL2022/050030 is a continuation-in-part of application No. 17/353,867, filed on Jun. 22, 2021, now Pat. No. 11,978,815.
Application No. 18/372,720 is a continuation-in-part of application No. 18/136,359, filed on Apr. 19, 2023.
Application No. 18/136,359 is a continuation of application No. PCT/IL2021/051269, filed on Oct. 27, 2021.
Application No. PCT/IL2021/051269 is a continuation-in-part of application No. 17/353,867, filed on Jun. 22, 2021, now Pat. No. 11,978,815.
Application No. 18/372,720 is a continuation-in-part of application No. 18/217,620, filed on Jul. 3, 2023.
Application No. 18/217,620 is a continuation of application No. PCT/IL2022/050030, filed on Jan. 10, 2022.
(63) Continuation-in-part of application No. 18/442,127, filed on Feb. 15, 2024.
Application No. 18/442,127 is a continuation of application No. PCT/IL2022/050899, filed on Aug. 18, 2022.
(63) Continuation-in-part of application No. 18/582,685, filed on Feb. 21, 2024.
Application No. 18/582,685 is a continuation of application No. PCT/IL2022/050941, filed on Aug. 29, 2022.
(60) Provisional application No. 63/238,802, filed on Aug. 31, 2021.
(60) Provisional application No. 63/238,803, filed on Aug. 31, 2021.
(60) Provisional application No. 63/238,810, filed on Aug. 31, 2021.
(60) Provisional application No. 63/088,535, filed on Oct. 7, 2020.
(60) Provisional application No. 62/785,282, filed on Dec. 27, 2018.
(60) Provisional application No. 62/785,282, filed on Dec. 27, 2018.
(60) Provisional application No. 62/982,536, filed on Feb. 27, 2020.
(60) Provisional application No. 63/167,660, filed on Mar. 30, 2021.
(60) Provisional application No. 63/106,666, filed on Oct. 28, 2020.
(60) Provisional application No. 63/234,727, filed on Aug. 19, 2021.
(60) Provisional application No. 63/238,808, filed on Aug. 31, 2021.
(60) Provisional application No. 63/239,969, filed on Sep. 2, 2021.
(60) Provisional application No. 63/238,802, filed on Aug. 31, 2021.
(60) Provisional application No. 63/238,803, filed on Aug. 31, 2021.
(60) Provisional application No. 63/238,810, filed on Aug. 31, 2021.

(51) Int. Cl. H02S 30/20; H01L 31/05

(52) U.S. Cl. CPC H02S 30/20; H01L 31/0508

(57) ABSTRACT

Enhanced flexible solar panels and photovoltaic devices, and methods and systems for producing them. A flexible Photovoltaic (PV) device includes: a flexible PV cell, configured to generate electricity from light; and a stretchable and compressible Patterned Metal Wiring Mesh, that is attached to a surface of said flexible PV cell, and that is configured to collect and aggregate PV-generated electricity from said flexible PV cell. The stretchable and compressible Patterned Metal Wiring Mesh is capable of stretching or compressing in response to mechanical forces that are applied to said flexible PV cell, while generally maintaining physical connectivity and electrical connectivity to electricity-generating regions of said PV cell. The Patterned Metal Wiring Mesh is embedded or attached onto, or at least partially embedded within, a Flexible Polymeric Support Foil that supports both the Patterned Metal Wiring Mesh and the flexible PV cell.

### CROSS-REFERENCE TO RELATED APPLICATIONS

This patent application is a Continuation of PCT international application number PCT/IL2022/050934, having an international filing date of Aug. 29, 2022, which is hereby incorporated by reference in its entirety.

The above-mentioned PCT/IL2022/050934 claims priority and benefit: from U.S. 63/238,802, filed on Aug. 31, 2021, which is hereby incorporated by reference in its entirety; and from U.S. 63/238,803, filed on Aug. 31, 2021, which is hereby incorporated by reference in its entirety; and from U.S. 63/238,810, filed on Aug. 31, 2021, which is hereby incorporated by reference in its entirety.

This patent application is also a Continuation-in-Part (CIP) of, and claims benefit and/or priority from: patent application U.S. Ser. No. 18/129,865, filed on Apr. 2, 2023, which is hereby incorporated by reference in its entirety.

The above-mentioned U.S. Pat. No. 18/129,865 is a Continuation of PCT international patent application number PCT/IL2021/051202, having an international filing date of Oct. 7, 2021, which is hereby incorporated by reference in its entirety.

The above-mentioned PCT/IL2021/051202 claims priority and benefit: (i) from U.S. 63/088,535, filed on Oct. 7, 2020, which is hereby incorporated by reference in its entirety; and (ii) from U.S. Ser. No. 17/353,867, filed on Jun. 22, 2021, which is hereby incorporated by reference in its entirety.

The above-mentioned U.S. Ser. No. 18/129,865 is also a Continuation-in-Part (CIP) of U.S. Ser. No. 17/353,867, filed on Jun. 22, 2021, which is hereby incorporated by reference in its entirety.

This patent application is also a Continuation-in-Part (CIP) of U.S. Ser. No. 17/353,867, filed on Jun. 22, 2021, which is hereby incorporated by reference in its entirety.

The above-mentioned U.S. Ser. No. 17/353,867 is a Continuation-in-Part (CIP) of U.S. Ser. No. 16/362,665, filed on Mar. 24, 2019, now patent number U.S. Pat. No. 11,081,606 (issued on Aug. 3, 2021), which is hereby incorporated by reference in its entirety; which claims priority and benefit from U.S. 62/785,282, filed on Dec. 27, 2018, which is hereby incorporated by reference in its entirety.

The above-mentioned U.S. Ser. No. 17/353,867 is also a Continuation-in-Part (CIP) of PCT international application number PCT/IL2019/051416, having an international filing date of Dec. 26, 2019, which is hereby incorporated by reference in its entirety.

The above-mentioned PCT/IL2019/051416 claims priority and benefit: (i) from U.S. Ser. No. 16/362,665, filed on Mar. 24, 2019, now patent number U.S. Pat. No. 11,081,606 (issued on Aug. 3, 2021), which is hereby incorporated by reference in its entirety, and (ii) from U.S. 62/785,282, filed on Dec. 27, 2018, which is hereby incorporated by reference in its entirety.

The above-mentioned U.S. Ser. No. 18/129,865 is also a Continuation-in-Part (CIP) of U.S. Ser. No. 17/802,335, filed on Aug. 25, 2022, which is hereby incorporated by reference in its entirety; which is a National Stage of PCT international application number PCT/IL2021/050217, having an international filing date of Feb. 25, 2021, which is hereby incorporated by reference in its entirety; which claims priority and benefit from U.S. 62/982,536, filed on Feb. 27, 2020, which is hereby incorporated by reference in its entirety.

This patent application is also a Continuation-in-Part (CIP) of, and claims benefit and/or priority from: patent application U.S. Ser. No. 18/372,720, filed on Sep. 26, 2023, which is hereby incorporated by reference in its entirety.

The above-mentioned U.S. Ser. No. 18/372,720 is a Continuation of PCT international application number PCT/IL2022/050339, having an international filing date of Mar. 29, 2022, which is hereby incorporated by reference in its entirety.

The above-mentioned PCT/IL2022/050339 claims priority and benefit from U.S. 63/167,660, filed on Mar. 30, 2021, which is hereby incorporated by reference in its entirety.

The above-mentioned PCT/IL2022/050339 also claims priority and benefit from PCT international application number PCT/IL2021/051202, having an international filing date of Oct. 8, 2021, which is hereby incorporated by reference in its entirety.

The above-mentioned PCT/IL2022/050339 also claims priority and benefit from PCT international application number PCT/IL2021/051269, having an international filing date of Oct. 27, 2021, which is hereby incorporated by reference in its entirety.

The above-mentioned PCT/IL2022/050339 also claims priority and benefit from PCT international application number PCT/IL2022/050030, having an international filing date of Jan. 10, 2022, which is hereby incorporated by reference in its entirety.

The above-mentioned PCT/IL2022/050339 also claims priority and benefit from patent application U.S. Ser. No. 17/353,867, filed on Jun. 22, 2021, which is hereby incorporated by reference in its entirety.

The above-mentioned U.S. Ser. No. 18/372,720 is also a Continuation-in-Part (CIP) of U.S. Ser. No. 18/136,359, filed on Apr. 19, 2023, which is hereby incorporated by reference in its entirety. The above-mentioned U.S. Ser. No. 18/136,359 is a Continuation of PCT international application number PCT/IL2021/051269, having an international filing date of Oct. 27, 2021, which is hereby incorporated by reference in its entirety. The above-mentioned PCT/IL2021/051269 claims priority and benefit: (i) from U.S. 63/106,666, filed on Oct. 28, 2020, which is hereby incorporated by reference in its entirety; and also, (ii) from U.S. Ser. No. 17/353,867, filed on Jun. 22, 2021, which is hereby incorporated by reference in its entirety.

The above-mentioned U.S. Ser. No. 18/372,720 is also a Continuation-in-Part (CIP) of U.S. Ser. No. 18/217,620, filed on Jul. 3, 2023, which is hereby incorporated by reference in its entirety; which is a Continuation of the above-mentioned PCT international application number PCT/IL2022/050030, having an international filing date of Jan. 10, 2022, which is hereby incorporated by reference in its entirety.

This patent application is also a Continuation-in-Part (CIP) of U.S. Ser. No. 18/442,127, filed on Feb. 15, 2024, which is hereby incorporated by reference in its entirety.

The above-mentioned U.S. Ser. No. 18/442,127 is a Continuation of PCT international application number PCT/IL2022/050899, having an international filing date of Aug. 18, 2022, which is hereby incorporated by reference in its entirety.

The above-mentioned PCT/IL2022/050899 claims priority and benefit: from U.S. 63/234,727, filed on Aug. 19, 2021, which is hereby incorporated by reference in its entirety; and from U.S. 63/238,808, filed on Aug. 31, 2021, which is hereby incorporated by reference in its entirety; and from U.S. 63/239,969, filed on Sep. 2, 2021, which is hereby incorporated by reference in its entirety.

This patent application is also a Continuation-in-Part (CIP) of U.S. Ser. No. 18/582,685, filed on Feb. 21, 2024, which is hereby incorporated by reference in its entirety.

The above-mentioned U.S. Ser. No. 18/582,685 is a Continuation of PCT international application number PCT/IL2022/050941, having an international filing date of Aug. 29, 2022, which is hereby incorporated by reference in its entirety.

The above-mentioned PCT/IL2022/050941 claims priority and benefit: from U.S. 63/238,802, filed on Aug. 31, 2021, which is hereby incorporated by reference in its entirety; and from U.S. 63/238,803, filed on Aug. 31, 2021, which is hereby incorporated by reference in its entirety; and from U.S. 63/238,810, filed on Aug. 31, 2021, which is hereby incorporated by reference in its entirety.

### FIELD

Some embodiments relate to the field of solar panels and photovoltaic (PV) devices.

### BACKGROUND

The photovoltaic (PV) effect is the creation of voltage and electric current in a material upon exposure to light. It is a physical and chemical phenomenon.

The PV effect has been used in order to generate electricity from sunlight. For example, PV solar panels absorb sunlight or light energy or photons, and generate electricity through the PV effect.

### SUMMARY

Some embodiments provide improved or enhanced solar panels, solar cells, PV cells and/or PV devices, and methods and systems for producing them. For example, a flexible Photovoltaic (PV) device includes: a flexible Photovoltaic (PV) device includes: a flexible PV cell, configured to generate electricity from light; and a stretchable and compressible Patterned Metal Wiring Mesh, that is attached to a surface of said flexible PV cell, and that is configured to collect and aggregate PV-generated electricity from said flexible PV cell. The stretchable and compressible Patterned Metal Wiring Mesh is capable of stretching or compressing in response to mechanical forces (and/or thermal changes) that are applied to said flexible PV cell, while generally maintaining physical connectivity and electrical connectivity to electricity-generating regions of said PV cell. The Patterned Metal Wiring Mesh is embedded or attached onto, or at least partially embedded within, a Flexible Polymeric Support Foil that supports both the Patterned Metal Wiring Mesh and the flexible PV cell.

Some embodiments provide other and/or additional benefits and/or advantages.

### BRIEF DESCRIPTION OF THE DRAWINGS

FIG. 1 is a photograph of a combined structure that includes a Patterned Metal Wiring Mesh which is glued or non-detachably attached to a Flexible Polymeric Support Foil, prepared for lamination or attachment onto (or beneath) a flexible solar cell, in accordance with some demonstrative embodiments of the present invention.

FIG. 2A is a schematic illustration of a Flexible Polymeric Support Foil having embedded therein or thereon a Patterned Metal Wiring Mesh, in accordance with some demonstrative embodiments.

FIG. 2B is a schematic illustration of a Flexible Polymeric Support Foil having embedded therein or thereon another type of Patterned Metal Wiring Mesh, in accordance with some demonstrative embodiments.

FIG. 2C is a schematic illustration of a Flexible Polymeric Support Foil having embedded therein or thereon another type of Patterned Metal Wiring Mesh, in accordance with some demonstrative embodiments.

FIG. 2D is a schematic illustration of a Flexible Polymeric Support Foil having embedded therein or thereon another type of Patterned Metal Wiring Mesh, in accordance with some demonstrative embodiments.

FIG. 3A is a photograph of a stretchable/compressible Patterned Metal Wiring Mesh that is already laminated on (or to, or beneath) a segmented (or trenched, or grooved, or singulated) generally-flexible solar cell or solar panel, in accordance with some demonstrative embodiments.

FIG. 3B is an enlarged or zoomed-in portion of the photograph of FIG. 3A, in accordance with some demonstrative embodiments.

FIG. 3C is a photograph of a solar module comprised of several stretchable/compressible Patterned Metal Wiring Mesh units that are laminated (or glued, or bonded) onto (or beneath) several respective generally-flexible solar cells, in accordance with some demonstrative embodiments.

FIG. 3D is a photograph of a rolled flexible solar module, formed of the Patterned Metal Wiring Mesh (or meshes), laminated onto (or beneath) and connecting a plurality of flexible solar cells, in accordance with some embodiments.

FIG. 4A is a photograph of another stretchable/compressible Patterned Metal Wiring Mesh, that can be laminated onto (or beneath) a segmented (or trenched/grooved/singulated) generally-flexible solar cell, in accordance with some demonstrative embodiments.

FIG. 4B is a photograph of another stretchable/compressible Patterned Metal Wiring Mesh, that can be laminated onto (or beneath) a segmented (or trenched/grooved/singulated) generally-flexible solar cell, in accordance with some demonstrative embodiments.

FIG. 4C is an enlarged or zoomed-in portion of the photograph of FIG. 4A.

FIG. 4D is an enlarged or zoomed-in portion of the photograph of FIG. 4B.

### DETAILED DESCRIPTION OF SOME DEMONSTRATIVE EMBODIMENTS

The Applicants have realized that conventional solar panels are typically rigid, heavy, cumbersome, brittle and/or fragile units, that are typically installed on roofs or in other locations (e.g., a solar energy park, a solar energy farm, a solar power plant).

The Applicants have realized that there is a need to improve and/or enhance the structure and/or configuration and/or production process of solar panels and other PV devices, and particularly of flexible solar panels and other flexible PV devices; in order to improve or enhance their efficiency, durability, mechanical resilience or durability, thermal resilience or durability, physical resilience or durability, mechanical strength, modularity, flexibility, flexing capability, bending capability, rolling capability, folding capability, and/or other characteristics; and/or in order to allow a more versatile utilization of such solar panels and other PV devices, and/or in order to enable efficient, light-weight, small form-factor, storage and/or transportation of such solar panels and other PV devices.

Some embodiments may be utilized in conjunction with PV devices and/or solar panels and/or components and/or methods that are described in patent number U.S. Pat. No. 11,081,606, titled “Flexible and rollable photovoltaic cell having enhanced properties of mechanical impact absorption”, which is hereby incorporated by reference in its entirety; and/or in conjunction with components, structures, devices, methods, systems and/or techniques that are described in patent application number U.S. Ser. No. 17/353,867, filed on Jun. 22, 2021, published as US 2021/0313478, which is hereby incorporated by reference in its entirety; and/or with solar panels or solar cells or PV devices that are singulated or segmented or trenched or grooved, or that are flexible and/or rollable and/or foldable, and/or that include “blind gaps” or non-transcending gaps or craters or grooves or trenches. Some embodiments may provide a flexible and rollable PV cell or solar cell; wherein a silicon body or semiconductor body or semiconductor substrate or semiconductor wafer has non-transcending craters or “blind gaps” or non-transcending grooves or trenches, that penetrate into between 50 percent and 99 percent of a total thickness of the semiconductor body (or silicon body, or wafer, or substrate), and that do not penetrate into an entirety of the total thickness of the semiconductor body (or silicon body, or wafer, or substrate); wherein said non-transcending craters or “blind gaps” increase flexibility and/or mechanical resilience and/or mechanical shock absorption of the PV cell. In some embodiments, some, or most, or all of the non-transcending craters or “blind gaps” contain a filler material having mechanical force absorption properties, which provides mechanical shock absorption properties and/or mechanical force dissipation properties to the PV cell.

The Applicants have realized that producing, deploying and/or utilizing a flexible solar cell or a flexible solar module or a flexible solar panel may involve one or more challenges. For example, realized the Applicants, in some implementations, one or more surfaces or regions or planes or layers of a generally-flexible solar panel may need to flex or to bend or to become curved, when mechanical forces or flexing forces are applied to the solar panel; whereas, one or more other surface or regions of planes or layers of that solar panel may need to remain non-flexed or non-curved, or may need to bend or to flex at a lesser degree or at a smaller curvature relative to other layers or regions. In some implementations, realized the Applicants, one or more layers or regions or surfaces of a generally-flexible solar panel may need to flex or to bend or to curve at a first curvature level; whereas, at the same time, one or more other layers or regions or surfaces of that same generally-flexible solar panel may need to flex or to bend or to curve at a second, different, curvature level (e.g., which may be larger, or smaller, than the first curvature level).

For example, realized the Applicants, in a generally-planar solar cell, that is flexed or bent to become curved or arc shaped, the central point of the top surface (or the bottom surface) of the solar panel may not move at all, whereas the edges of the top surface (or the bottom surface) of that same solar panel may need to “travel” downwardly as part of the flexing or bending of the solar cell; and thus, different regions or different points of the solar cell may need to “travel” (or to be displaced) a different distance in order for the solar cell to achieve a certain curvature.

In some embodiments, realized the Applicants, some or almost all of the regions or layers of the generally-flexible solar cell may need to have the capability to move or to flex, except for a “zero plane” or a “zero column” or a “zero point” which may not, or which should not, move or travel or flex. In some embodiments, different regions and/or layers, as well as different components of the generally-flexible solar cell, may need to accommodate different level of displacement or curvature or stretching or bending or compression; due to the different characteristics and/or functionalities of such different regions and/or components, and/or due to physical dimensions that require different regions to achieve different arc length or radius length due to their relative location.

In some embodiments, realized the Applicants, one particular plane or column or region of the solar panel may be configured as a non-moving/non-traveling plane or column or region;

whereas other, or all the other, regions or planes of that solar panel should be able to move, flex, bend and/or be displaced relative to their idle (non-flexed) location.

The Applicants have realized that some generally-flexible solar panels may be produced, for example, by grooving or trenching or segmenting or forming non-transcending trenches or grooves or craters or “blind gaps”, in the silicon body or silicon bulk or semiconductor wafer or semiconductor substrate; that penetrate some (but not all) of the total thickness of that silicon or wafer or semiconductor; to provide flexibility and/or bending capabilities, as mentioned above, during deployment and/or utilization and/or transportation and/or storage. Such segmentation or grooving or trenching may further allow the flexible solar panel to be rolled into a roll (e.g., cylinder shaped), for efficient storage and/or transportation.

The term “Patterned Metal Wiring Mesh”, as used herein, may include a metal wiring mesh or metal wiring network, or a plurality of parallel and/or intersecting metal wires, and/or a metal foil which may be wrinkled and/or crumbled or which may have metallic protrusions and/or ribs and/or valleys and/or craters and/or wrinkles and/or non-smooth surface-portions, and/or other pre-defined structure or a patterned metal wiring network or mesh; and including, for example, metal wirings that are entirely or mostly curved and/or curly and/or wavy and/or wave-shaped and/or sinusoid and/or zigzag structured, and/or metal wirings that have at least some portions or segments that are curved and/or curly and/or wavy and/or wave-shaped and/or sinusoid and/or zigzag structured; or a combination of two or more of the above features and/or structure in one singular or unified metal wiring mesh or network or sheet.

In accordance with some embodiments, the Patterned Metal Wiring Mesh is stretchable and compressible; and is capable of stretching and/or expanding at least some of its metal segments or wire portions, in response to mechanical forces and/or thermal changes, and/or in response to operations such as rolling or folding or bending or flexing or curving or un-rolling or un-folding; and/or is capable of increasing the length of at least some of its metal segments or wire portions in response to such forces and/or operations; and/or is capable or causing at least some portions of its metal segments or wire portions to reduce their curvature, or to become more linear and/or less curved, in response to such forces and/or operations (e.g., causing a wire-segment that was curly or was U-shaped, to become linear or almost-linear in response to such forces and/or operations, or to become a curved arc that covers a smaller ratio of a full circle compared to the original coverage of an idle or non-stretched state of that wire-segment); and that is capable of compressing and/or shrinking and/or condensing at least some of its metal segments or wire portions, in response to mechanical forces and/or thermal changes, and/or in response to operations such as rolling or folding or bending or flexing or curving or un-rolling or un-folding; and/or is capable of decreasing the length of at least some of its metal segments or wire portions in response to such forces and/or operations; and/or is capable of causing at least some portions of its metal segments or wire portions to increase their curvature, or to become less linear and/or more curved, in response to such forces and/or operations (e.g., causing a wire-segment that was linear or almost-linear to become curly or U-shaped in response to such forces and/or operations, or to become a curved arc that covers a larger ratio of a full circle compared to the original coverage of an idle or non-compressed state of that wire-segment).

The terms “Flexible Support Foil” or “Flexible Polymeric Support Foil”, as used herein, may include a flexible and/or rollable and/or foldable and/or bendable support structure or support substrate or support plane or generally-planar (in an idle non-rolled/non-bent state) structure; typically formed of one or more polymers; which is capable of supporting or holding or carrying thereon the Patterned Metal Wiring Mesh, or that can be connected or attached or glued beneath the Patterned Metal Wiring Mesh, or which may otherwise hold the Patterned Metal Wiring Mesh, or (in some implementations) which may have at least some portions of the Patterned Metal Wiring Mesh embedded within the Flexible Polymeric Support Foil (e.g., such that at least some metal segments or wire portions of the Patterned Metal Wiring Mesh are within (or, are beneath the top surface of) the Flexible Polymeric Support Foil while at least some other metal segments or wire portions of the Patterned Metal Wiring Mesh are protruding out of (or, are above the top surface of) the Flexible Polymeric Support Foil.

The combination of the Flexible Polymeric Support Foil, carrying or holding or being glued or bonded or non-detachably attached or non-removably attached to the Patterned Metal

Wiring Mesh, may have the flexibility properties of each one of the two components; such that curving or flexing or bending or rolling or folding of the combined component, or performing opposite operations thereto (e.g., un-folding, un-rolling), may cause both of these components to adapt to the mechanical forces that were applied and to the operations that were performed; such that the Flexible Polymeric Support Foil may become curved or rolled, while the Patterned Metal Wiring Mesh (or, at least some metal portions or wire segments thereof) may stretch or may become elongated or may become more linear or less curvy; and while avoiding or preventing disconnection or ripping or detachment of all, or most, or at least some, of the metal segments or wire segments of the Patterned Metal Wiring Mesh; and while avoiding or preventing displacement of distancing of all, or most, or at least some, of the metal segments or wire segments of the Patterned Metal Wiring Mesh, from one or more electricity-generating regions of the solar cell or PV device; and while maintaining mechanical connectivity and electrical connectivity of the Patterned Metal Wiring Mesh (or, in some embodiments, of at least some, or most, of its metal segments or wire segments) with the nearby electricity-generating regions of the solar cell or PV device.

In some embodiments, optionally, the Flexible Polymeric Support Foil may be transparent or translucent; or may enable passage therethrough of at least 50 or 75 percent of incoming light; for example, enabling to produce a double-sided flexible solar cell, or enabling the flexible solar cell to absorb light from two or more surfaces or directions.

The Applicants have realized that out of the various components of a generally-flexible solar panel, metal wires (that collect and/or aggregate the PV-generated electricity) may be vulnerable to mechanical and/or operational damage upon flexing or bending or curving or rolling of a generally-flexible solar panel. For example, realized the Applicants, Patterned Metal Wiring Mesh may be used to interconnect the segmented sub-regions of a solar panel and particularly of a flexible solar panel, that are segmented by rows and/or columns of the above-mentioned trenches or grooves or non-transcending craters in the silicon (or wafer, or semiconductor body); and such Patterned Metal Wiring Mesh may be laminated with (or may be implemented as, or accompanied by, or glued or bonded to, or may be non-detachably attached to, or may be non-removably attached to) a Flexible Polymeric Support Foil.

In accordance with some embodiments, an Patterned Metal Wiring Mesh (that is attached to, or mounted on, or laminated on or with, a Flexible Polymeric Support Foil) collects and/or aggregates PV-generated electricity from a plurality of (or array, or matrix) of neighboring segments of a solar panel. The Patterned Metal Wiring Mesh may be stretchable and/or compressible, in at least one side or one surface, and/or along at least one direction (e.g., length, or width, or both length and width) in order to accommodate (and withstand) flexing and/or bending and/or curving and/or rolling of the entirety of the solar panel or of a particular region of the solar panel; and in order to accommodate and withstand repeated bending and un-bending or counter-bending, or repeated rolling and un-rolling, or repeated flexing and un-flexing, or repeated curving and un-curving, or repeated folding and un-folding, or a combination of such operations, which may be performed onto the entirety of the generally-flexible solar panel or which may be performed onto particular region(s) of the generally-flexible solar panel.

The Applicants have realized that in conventional solar panels, an electrode mesh or a plurality of metal wires of a conventional generally-flexible solar panel, that collect and/or aggregate PV-generated electricity, may (in some situations) get damaged or harmed due to mechanical forces and/or bending and/or flexing and/or curving and/or rolling of the solar panel (or regions thereof). The Applicants have realized that such mechanical forces and/or operations may cause some electrical contacts to rip or break or tear; or to get damaged, or to become loose, or to become unreliable or malfunctioning or dysfunctional. The Applicants have realized that flexing and/or bending and/or folding and/or rolling of a generally-flexible solar panel, may (in some situations) cause some regions of the solar panel to lose their electrical contact to the metal wires due to the formed curvature, and/or due to mechanical forces that break such electrical contacts due to localized forces on particular segmented sub-regions (or miniature PV cells) of the solar panel, and/or due to formation of cracks or micro-cracks.

Some embodiments of the present invention may thus provide a generally-flexible solar panel or solar module, which may be flexible and/or rollable and/or bendable and/or foldable, and which may have improved or enhanced flexibility, and/or may have increased or enhanced mechanical resilience; and particularly, its Patterned Metal Wiring Mesh, that collects and/or aggregates and/or transports PV-generated electricity from one or more electricity-generating regions of the solar cell, may have enhanced resilience to mechanical forces and to flexing or bending or curving or folding or rolling (as well as un-rolling or un-folding or counter-bending) operations; and which may eliminate or prevent or reduce breakage of, or damage to, or mechanical disconnection of, or electrical disconnection of, some or most or all of the metal segments of such Patterned Metal Wiring Mesh. Some embodiments may provide a generally-flexible solar panel having a stretchable and/or compressible Patterned Metal Wiring Mesh for collecting and/or aggregating PV-generated electricity from (and/or for transporting the PV-generated electricity away from) the plurality of segmented regions of the solar panel, to eliminate or reduce electrical connectivity failures and/or mechanical damage.

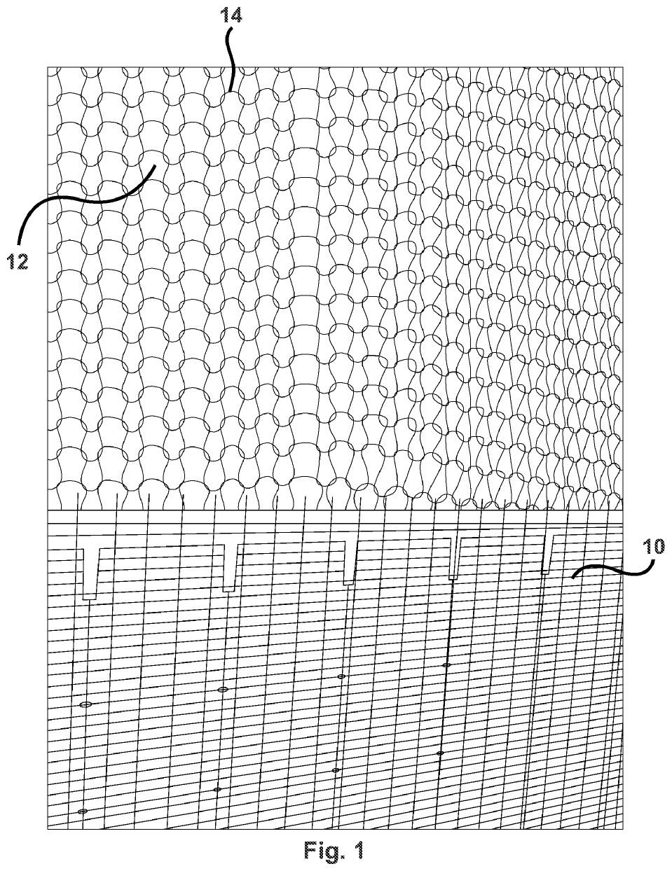

Reference is made to FIG. 1, which is a photograph of a combined structure 12 that includes a Patterned Metal Wiring Mesh which is glued or non-detachably attached to a Flexible

Polymeric Support Foil, prepared for lamination or attachment onto (or beneath) a flexible solar cell 10, in accordance with some demonstrative embodiments of the present invention. The Flexible Polymeric Support Foil may be formed of one or more polymer layers; for example, polyethylene terephthalate (PET) and/or polyolefin and/or other suitable polymers. In some embodiments, the Flexible Polymeric Support Foil may include a support layer having one or more added layer(s) of adhesive or glue or bonding agent; for example, polyolefin adhesive, Ethylene Vinyl Acetate (EVA) or Polyethylene vinyl acetate (PEVA), pressure sensitive adhesive (PSA), heat activated adhesive, bonding agent(s), gluing agent(s), and/or other suitable materials.

A network or mesh or matrix of metal wiring 14 is partially embedded within the combined structure 12 (which is a combination of the Patterned Metal Wiring Mesh and the Flexible Polymeric Support Foil), such that a part or a surface of the metal wiring 14 is exposed on the surface of the combined structure 12, and enables electrical connectivity with the solar panel onto which (or beneath which) the combined structure 12 maybe laminated or attached; such as, on top of (or above) a suitable electricity-generating surface or region of the solar panel; or beneath (or under) a suitable electricity-generating surface or region of the solar panel; depending on the particular implementation.

The metal wiring 14, which is the Patterned Metal Wiring Mesh, may be formed of one or more conductive material(s), for example, tin, aluminum, copper, tinned copper, silver, copper that is covered/coated by tin, an alloy of two or more metals, a combination of two or more metals, or the like. In some embodiments, some or all the metal wiring 14 or the Patterned Metal Wiring

Mesh may optionally be coated with tin and/or with one or more metals, or with an alloy, having a relatively low melting point (e.g., indium, bismuth, a combination of them, or the like).

The metal wiring 14 or the Patterned Metal Wiring Mesh is structured and formed as a mesh or a network, having a particular, pre-defined, two-dimensional structure or layout or three-dimensional structure or layout (e.g., although it is generally flat and thus may almost be regarded as a two-dimensional pattern), in order to provide two-dimensional (or, in some implementations, three-dimensional) stretching capability and/or compressing capability towards four directions (or, towards six direction). The pre-defined layout or pattern of the metal wiring 14 or the Patterned Metal Wiring Mesh enables it to have and to maintain multiple electrical connection points (and/or mechanical connection points) with the solar cell regions that generate electricity via the PV effect; forming electric current paths from any area or region of the Patterned Metal Wiring Mesh.

In some embodiments, optionally, Patterned Metal Wiring Mesh may be formed by using knitting operations, weaving operations, sewing operations, threading operations, stitching operations, knotting operations, welding operations, gluing/bonding operations, adhesive-based operations, and/or other suitable operations; or a combination of two or more of such operations.

The Flexible Polymeric Support Foil having the Patterned Metal Wiring Mesh embedded therein or attached thereto, is laminated or glued or bonded or non-detachably attached to the segmented (or trenched, or grooved) generally-flexible solar cell 10, or beneath it or under it, or on top of it or above it; or may be laminated or glued or bonded to a larger solar panel or solar module which may comprise a plurality of such solar cells. The Patterned Metal Wiring Mesh is in contact with the solar cell 10, or at least with (or, exactly with) the electricity-generating regions of the solar cell 10; and provides the required electrical conductivity to collect and/or aggregate and/or transport the PV-generated electricity. The laminated solar cell, or a set or array or matrix of such interconnected soar cells that together form a solar module or a solar panel, may be rolled or folded or bent or flexed, without the risk of losing mechanical connectivity and/or electrical connectivity of the electricity-generating regions and the Patterned Metal Wiring Mesh, and/or without inflicting any (or excessive, or significant) mechanical stress or mechanical damage on the segmented sub-regions of the solar cell or solar panel, and/or without causing mechanical breakage or damage to all (or most, or at least some) of the Patterned Metal Wiring Mesh.

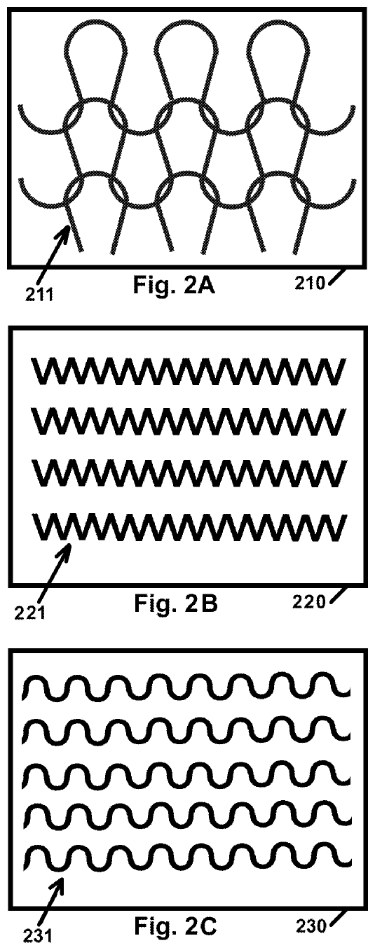

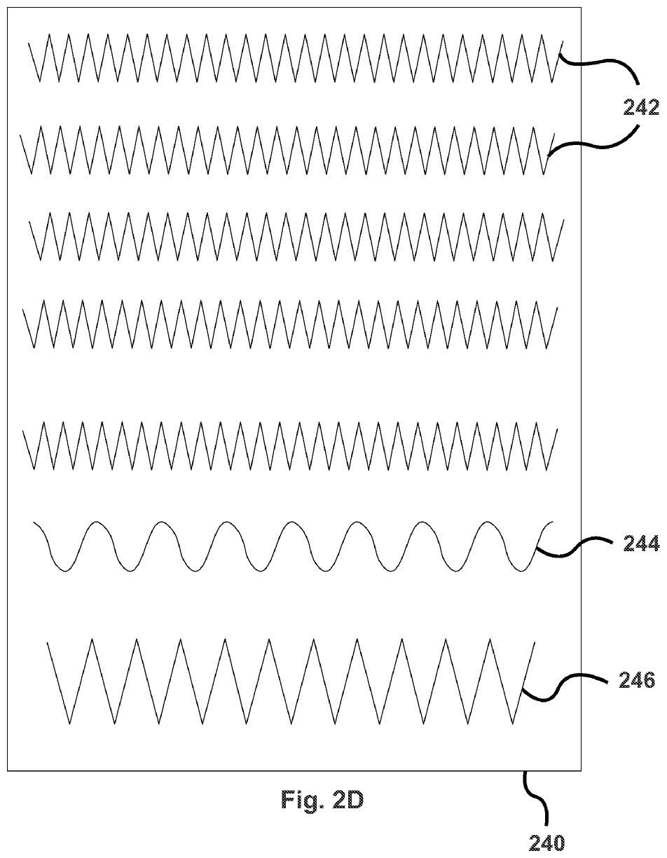

Reference is made to FIG. 2A, which is a schematic illustration of a Flexible Polymeric Support Foil 210 having embedded therein or thereon a Patterned Metal Wiring Mesh 211, in accordance with some demonstrative embodiments. The Patterned Metal Wiring Mesh 211 may have a structure or layout that is generally similar to that shown as element 14 in FIG. 1; and may be generally similar to a weft knit structure of fabric, or it may be a weft knit structure formed of thin metal wires. The Patterned Metal Wiring Mesh 211, or at least some portions or segments thereof, is stretchable and/or compressible, and can increase its two-dimensional area or size (or the length and/or shape of a particular segment or region thereof) in response to stretching/compressing/bending/folding/rolling/mechanical forces, and can three-dimensionally adapt or can two-dimensionally adapt (or, can at least one-dimensionally adapt) to such forces and/or operations.

Reference is made to FIG. 2B, which is a schematic illustration of a Flexible Polymeric Support Foil 210 having embedded therein or thereon a Patterned Metal Wiring Mesh 221, in accordance with some demonstrative embodiments. The Patterned Metal Wiring Mesh 221 may have a structure or layout which comprises generally parallel zig-zag lines or zig-zag patterns; or (in other implementations) intersecting zig-zag lines. The Patterned Metal Wiring Mesh 221, or at least some portions or segments thereof, is stretchable and/or compressible, and can increase its two-dimensional area or size (or the length and/or shape of a particular segment or region thereof) in response to stretching/compressing/bending/folding/rolling/mechanical forces, and can three-dimensionally adapt or can two-dimensionally adapt (or, can at least one-dimensionally adapt) to such forces and/or operations.

Reference is made to FIG. 2C, which is a schematic illustration of a Flexible Polymeric Support Foil 210 having embedded therein or thereon a Patterned Metal Wiring Mesh 231, in accordance with some demonstrative embodiments. The Patterned Metal Wiring Mesh 231 may have a structure or layout which comprises generally parallel sinusoid lines, or waves, or wavy lines or wave-shaped lines, or parallel curly lines, or rounded zig-zag lines, or curling or swirling lines, or lines having horseshoe segments or U-shape segments, or curly lines shaped as interconnected sideways S segments, or the like. The Patterned Metal Wiring Mesh 231, or at least some portions or segments thereof, is stretchable and/or compressible, and can increase its two-dimensional area or size (or the length and/or shape of a particular segment or region thereof) in response to stretching/compressing/bending/folding/rolling/mechanical forces, and can three-dimensionally adapt or can two-dimensionally adapt (or, can at least one-dimensionally adapt) to such forces and/or operations.

Reference is made to FIG. 2D, which is a schematic illustration of a Flexible Polymeric Support Foil 210 having embedded therein or thereon a Patterned Metal Wiring Mesh 241 (comprised of a plurality of metal wire segments, such as segments 242, 244, 246), in accordance with some demonstrative embodiments. The Patterned Metal Wiring Mesh 241 may have a structure or layout which comprises generally parallel sinusoid lines, or waves, or wavy lines or wave-shaped lines, or parallel curly lines, or rounded zig-zag lines, or curling or swirling lines, or lines having horseshoe segments or U-shape segments, or curly lines shaped as interconnected sideways S segments, or the like. The Patterned Metal Wiring Mesh 241, or at least some portions or segments thereof, is stretchable and/or compressible, and can increase its two-dimensional area or size (or the length and/or shape of a particular segment or region thereof) in response to stretching/compressing/bending/folding/rolling/mechanical forces, and can three-dimensionally adapt or can two-dimensionally adapt (or, can at least one-dimensionally adapt) to such forces and/or operations.

FIG. 2D demonstrates several features which may be implemented and/or combined. First, it demonstrates that several different types of wire layouts (zig-zag 242, wave or sinusoid 244) may be combined and may be co-located in a single, unified, Patterned Metal Wiring Mesh 241 that is glued or attached to a single, unified, Flexible Polymeric Support Foil 240; those segments (242, 244, 246) are shown as discrete or separate from each other or having a distance among them; yet in some implementations they may be touching or intersecting or crossing each other. Second, it demonstrates that two (or more) wire layouts of the same Patterned Metal Wiring Mesh 241 may be of the same general type, but may still have different characteristics; for example, condensed or high-density or low-height zig-zag wire 242 is co-located in (or on) the same Flexible Polymeric Support Foil with relaxed or low-density zig-zag wire 246. Third, it demonstrates that spacing or distances among wires or segments of the Patterned Metal Wiring

Mesh 241 may be uniform or fixed or constant (as in the top three zig-zag lines 242), or may vary across wires or across lines (e.g., the fifth zig-zag line from the top is distanced from the other four), or may be a combination of fixed distances as well as varying distances in a single Patterned Metal Wiring Mesh 241.

It is clarified that the various wire layout(s) and/or their positioning, lengths, shapes, locations, and/or other characteristics, are not merely a “design choice” and are not merely ornamental or arbitrary; but rather, they may be configured and/or selected in order to achieve particular functional goals. In a first example, the Patterned Metal Wiring Mesh of a first particular implementation of a flexible solar panel may be configured or structured to have zig-zag metal wires, as this particular structure may be shown to provide the best resilience for a first particular purpose; whereas, the Patterned Metal Wiring Mesh of a second particular implementation of a flexible solar panel may be configured to have wave-shaped or curly or sinusoid metal wires, as this particular structure may be shown to provide the best resilience for a second, particular, purpose (e.g., as a non-limiting example for demonstrative purposes only: in some implementations, a flexible solar panel that is intended to float on a body of water, may have different resilience goals relative to those of a flexible solar panel that is intended to be a part of a road divider or a vehicular roof; and therefore, these two different types or usage goals of these two different PV devices, may be accommodated by providing different shapes or structure of their respective Patterned Metal Wiring Mesh). In a second example, two or more different layouts of metal wires may be combined and co-located in a single Patterned Metal Wiring Mesh and in a single flexible solar panel, and may be connected or attached to a single Flexible Polymeric Support Foil, in order to avoid a “single point of failure” and in order to increase the average resilience of the total resilience of the solar panel; such that, for example, a particular abrupt mechanical force may break or damage all (or most) of the zig-zag wires of that Patterned Metal Wiring Mesh, yet may not break or may not damage (at all, or to the same degree) the co-located sinusoid or curly or wave-shaped wires (or vice versa). In a third example, the particular type or structure or layout of the metal wire(s), or the particular layout of the stretchable and compressible Patterned Metal Wiring Mesh, may be tailored or configured or selected based on other characteristics of the solar panel (e.g., its deployment location or environment; whether or not it is intended to be rolled; whether or not it is intended to be folded; whether or not it is intended to be placed in long-term storage; whether or not it is intended to be placed or used in a wet environment or over a body of water; or the like).

As demonstrated in FIG. 2D, the Patterned Metal Wiring Mesh with the attached Flexible Polymeric Support Foil may be prepared for laminating onto (or beneath) a singulated or segmented generally-flexible solar cell or solar panel. The metal wiring (242, 244, 246) are capable of stretching and/or compressing, and/or shrinking in length and/or expanding in length, and/or bending, and/or gaining height or reducing their height (relative to the surface or general plane of the Flexible Polymeric Support Foil) without becoming broken or damaged; due to their particular pre-defined shape and layout and pattern; and may thus render or provide more flexibility or increased flexibility (as well as mechanical resilience and thermal resilience) to the solar cell or solar panel, or may functionally support and may remain functionally connected to a bent or folded or rolled or flexed or curved solar cell or solar panel; to a significantly greater extent relative to a simple set of straight-line wires or an intersecting group of straight-line wires.

In accordance with some embodiments, any suitable type of conductive Patterned Metal Wiring Mesh may be used, and may be embedded within or onto the Flexible Polymeric Support Foil; as long as such Patterned Metal Wiring Mesh (or, most of its wire segments or metal segments; or, at least some of its wire segments or metal segments) has at least one direction by which it can be stretched or compressed or expand or shrink, or become more curvy or less linear, or become less curvy and more linear.

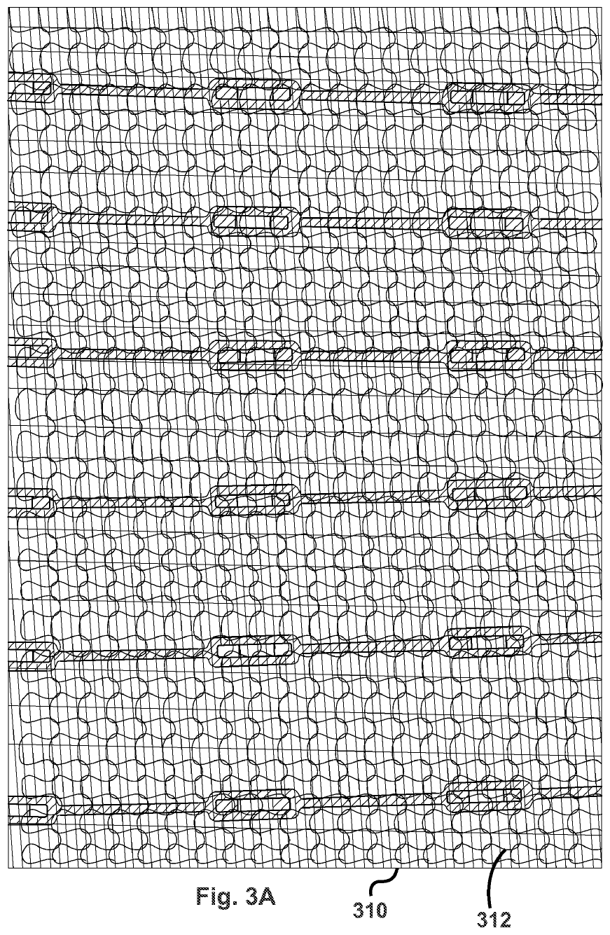

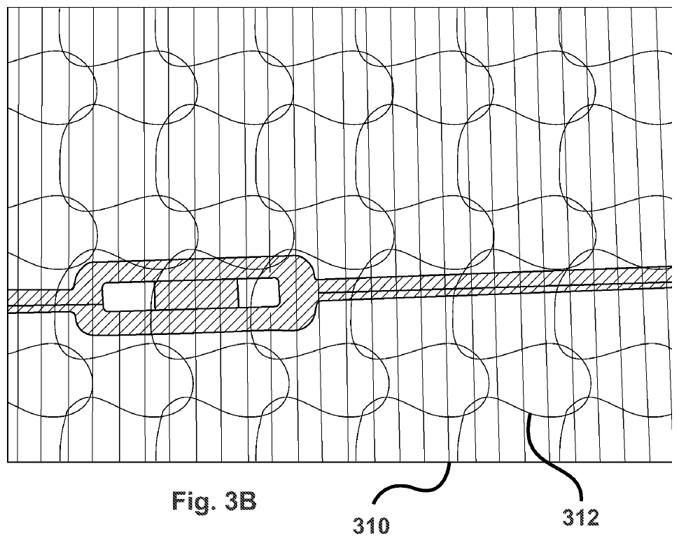

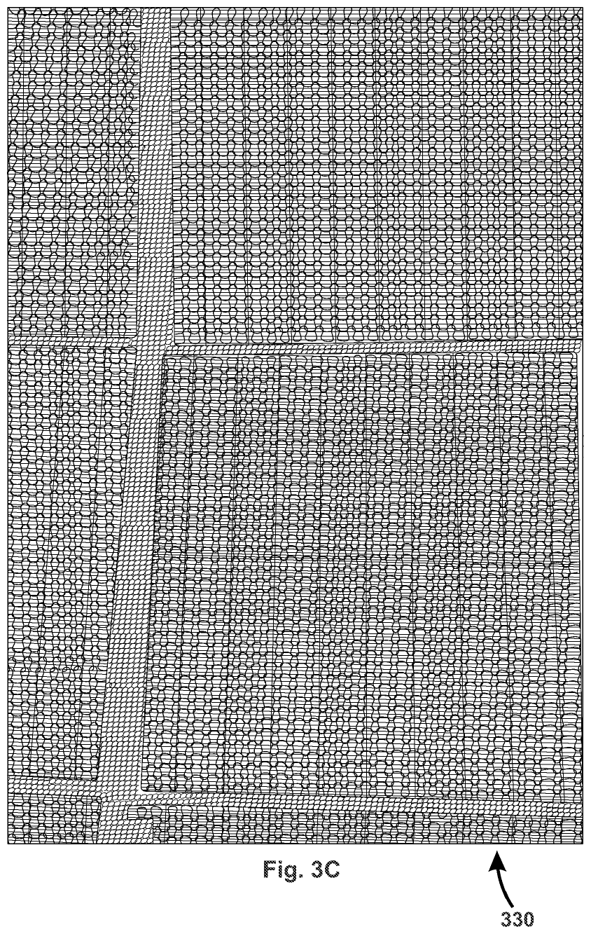

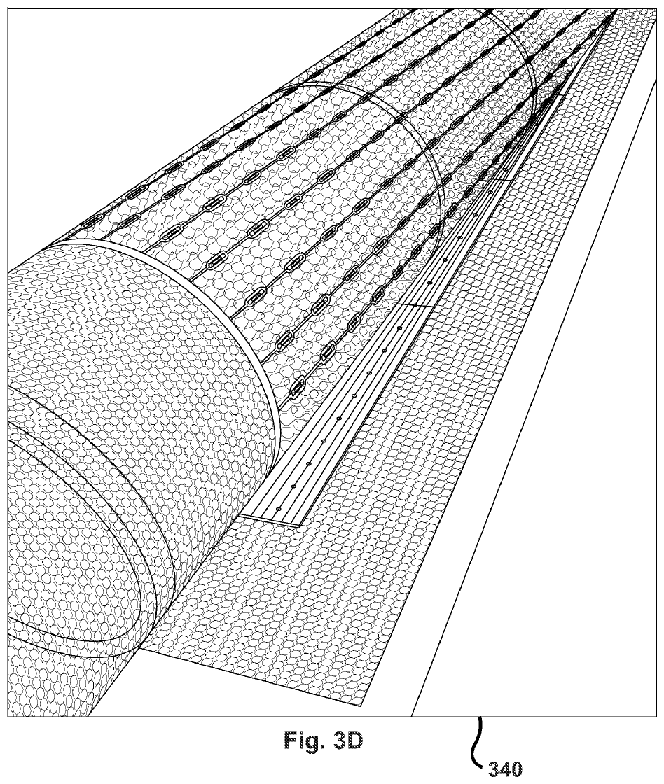

Reference is made to FIG. 3A, which is a photograph of a stretchable/compressible Patterned Metal Wiring Mesh 312 that is already laminated on (or to, or beneath) a segmented (or trenched, or grooved, or singulated) generally-flexible solar cell 310 or solar panel, in accordance with some demonstrative embodiments. Reference is also made to FIG. 3B, which is an enlarged or zoomed-in portion of that photograph, in accordance with some demonstrative embodiments. For example, the Flexible Polymeric Support Foil and its Patterned Metal Wiring Mesh, may be laminated or glued or bonded onto (or beneath) a flexible solar cell. The metal wiring of the Patterned Metal Wiring Mesh 312 have a pattern or structure or layout that is configured to adapt to mechanical forces, and is configured to maintain or preserve the connectivity of the solar cell 310 and to maintain the electrical connectivity of the Patterned Metal Wiring Mesh 312 to the electricity-generating regions of the solar cell 310; while also providing at least some degree(s) of freedom to the solar cell 310 to maintain its flexibility without limiting its ability to be curved or bent or rolled or folded in any direction/s (or, in at least one direction) relative to the cuts or segments or grooves or trenches or segmentation lines of the solar cell.

Reference is made to FIG. 3C, which is a photograph of a solar module 330 comprised of several stretchable/compressible Patterned Metal Wiring Mesh units that are laminated (or glued, or bonded) onto (or beneath) several respective generally-flexible solar cells, in accordance with some demonstrative embodiments. The number of the connected solar cells, and the size of the overall solar module, may be configured according to particular functional goals and/or according to the environment or location in which the solar module will be deployed.

In accordance with some embodiments, optionally, a single, unified, large-size stretchable/compressible Patterned Metal Wiring Mesh may be glued or bonded or laminated or connected to a plurality of flexible solar cells; or, a plurality of such stretchable/compressible Patterned Metal Wiring Mesh units may be glued or bonded or laminated or connected to a plurality of flexible solar cells; to thus create a larger-size solar module, whose size is larger than the size of a single solar cell. In some embodiments, the solar module is flexible and may be rollable and/or foldable.

Reference is made to FIG. 3D, which is a photograph of a rolled flexible solar module 340, formed of the Patterned Metal Wiring Mesh (or meshes), laminated onto (or beneath) and connecting a plurality of flexible solar cells, in accordance with some embodiments. The solar module 340 may be rolled around itself, or may be rolled around a cylindrical object or other suitable core. The rolled-up solar module 340 may then be efficiently stored and/or transported, in a space-saving manner or in a small form-factor.

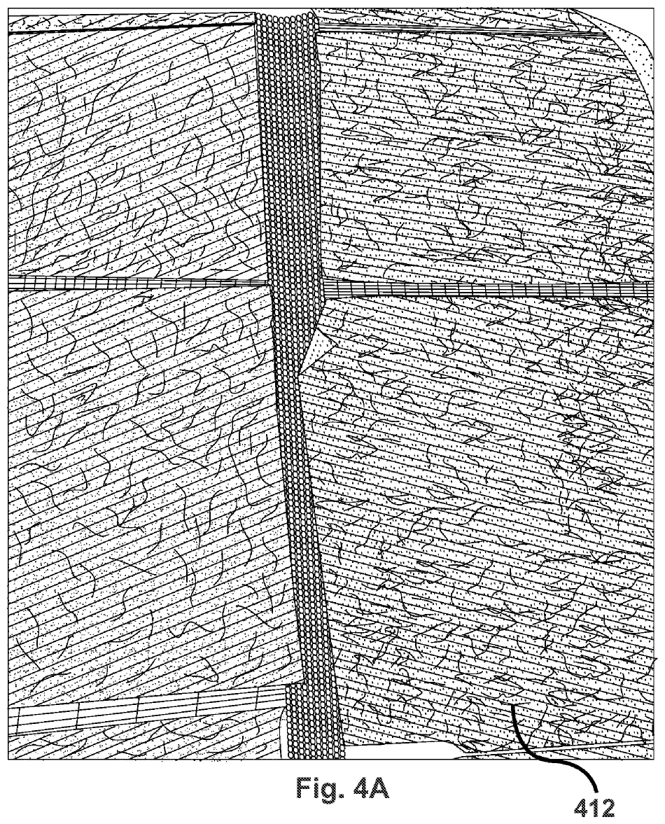

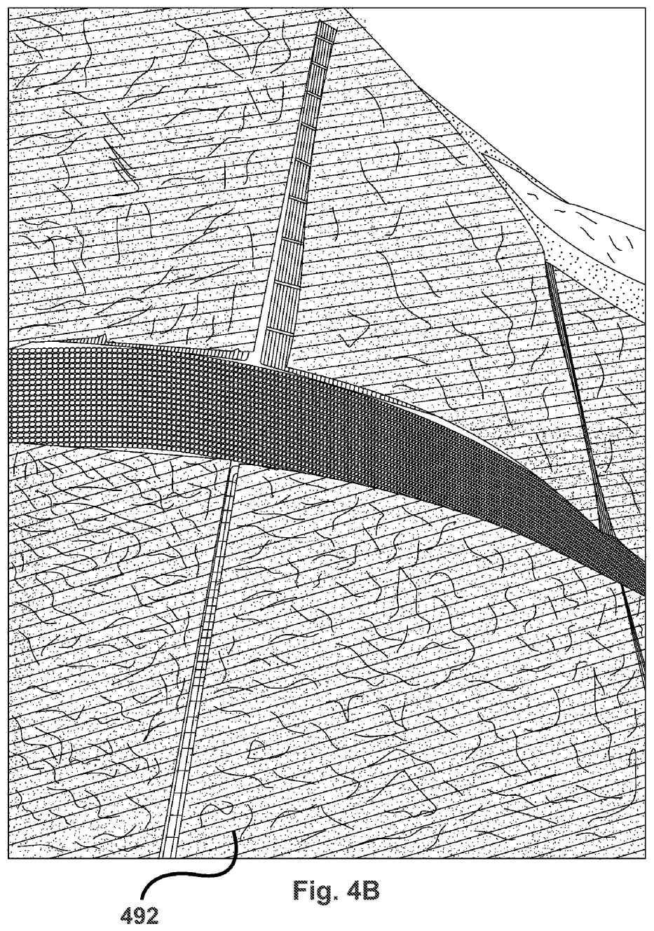

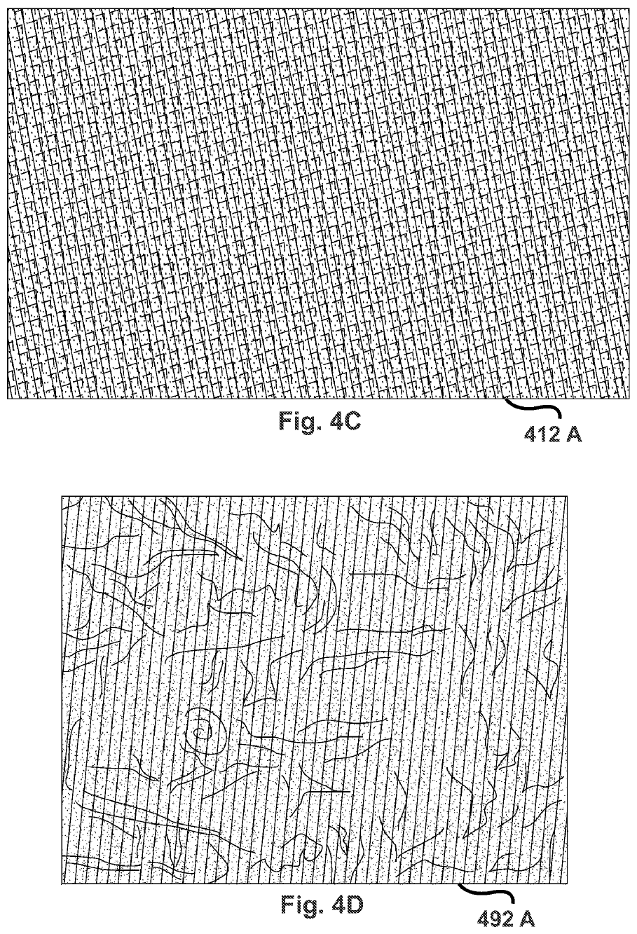

Reference is made to FIG. 4A, which is a photograph of another stretchable/compressible Patterned Metal Wiring Mesh 412, that can be laminated onto (or beneath) a segmented (or trenched/grooved/singulated) generally-flexible solar cell, in accordance with some demonstrative embodiments. Reference is also made to FIG. 4C, which is an enlarged or zoomed-in portion 412A of that photograph.

Reference is further made to FIG. 4B, which is a photograph of another stretchable/compressible Patterned Metal Wiring Mesh 492, that can be laminated onto (or beneath) a segmented (or trenched/grooved/singulated) generally-flexible solar cell, in accordance with some demonstrative embodiments. Reference is also made to FIG. 4D, which is an enlarged or zoomed-in portion 492A of that photograph.

As demonstrated in FIGS. 4A to 4D, instead of using a network of discrete metal wires, a thin metal foil is utilized (e.g., formed of aluminum and/or other metal or metals), such that the thin metal electrode foil is intentionally crumpled and/or intentionally wrinkled, and is non-smooth and is not entirely planar, and/or has non-smooth regions or non-planar regions; and/or has small uneven surfaces, or has a surface with small craters and/or valleys and/or protrusions and/or ribs, and/or has a three-dimensional zig-zag pattern of protrusions and craters (or protrusions and intermediate valleys among them); or has a protruding ribbed surface; in order to provide stretching ability and/or compressing ability and/or flexibility and/or curving ability to such Patterned Metal Wiring Mesh 412 or 492, as well as to the solar cell to which it is bonded or glued or laminated or attached. The wrinkles or crumples of the Patterned Metal Wiring Mesh 412 or 492 enable it, and further enable the attached solar cell, to bend or curve or flex, without causing the Patterned Metal Wiring Mesh (or at least most of it; or at least some of it) to tear or to rip or to mechanically disconnect or to electrically disconnect, and while maintaining electrical continuity and connectivity.

In accordance with some embodiments, various other types of Patterned Metal Wiring Mesh may be used, as long as they maintains their stretching/compressing capabilities while laminated within (or onto, or beneath) a Flexible Polymeric Support Foil; and can be laminated or glued or bonded or attached to a segmented, flexible, solar cell (or to a plurality of neighboring solar cells, forming a solar module), while maintaining the connectivity of the solar cell or solar module.

Additional Features, Which May be Combined with any of the Above-Mentioned Features, and/or that May Implement any of the Above-Mentioned Features:

In accordance with some embodiments, each of the solar cells is rollable and flexible by itself; and is a single PV device or is a single PV article, that is comprised of a single semiconductor substrate or a single semiconductor wafer or a single semiconductor body; which is monolithic, e.g., is currently, and has been, a single item or a single article or a single component that was formed as (and remained) a single component; such that each solar cell is not formed as a collection or two or more separate units or as a collection of two or more entirely-separated or entirely-discrete or entirely-gapped units that were arranged or placed together in proximity to each other yet onto a metal foil or onto a metal film or onto a flexible or elastic foil or film.

In some embodiments, each single solar cell that is flexible and rollable by itself, is not a collection and is not an arrangement and is not an assembly of multiple discrete solar cells of PV modules, that each one of them has its own discrete and fully separated semiconductor substrate and/or its own discrete and fully separated semiconductor wafer and/or its own discrete and fully separated semiconductor body, and that have been merely placed to assembled or arranged together (or mounted together, or connected together) onto or beneath a flexible foil or a flexible film; but rather, the each single solar cell has a single unified semiconductor substrate or semiconductor body or semiconductor wafer that is common to, and is shared by, all the sub-regions or areas or portions of that single solar cell which includes therein (in that unified single semiconductor substrate or wafer or body) those non-transcending craters or non-transcending gaps or “blind gaps” that penetrate only from one side (and not from both sides), which do not reach all the way through and do not reach all the way to the other side of the unified single semiconductor substrate or wafer or body.

In some embodiments, each solar cell may be, or may include, a mono-crystalline PV cell or solar panel or solar cell, a poly-crystalline PV cell or solar panel or solar cell, a flexible PV cell or solar cell that is an Interdigitated Back Contact (IBC) solar cell having said semiconductor wafer with said set of non-transcending gaps, and/or other suitable type of PV cell or solar cell.

Some portions of the discussion above and/or herein may relate to regions or segments or areas, of the semiconductor body or substrate or wafer (or PV cell, or PV device); yet those “segments” are still touching each other and/or inherently connected to each other and/or non-separated from each other, as those “segments” are still connected by at least a thin portion or a thin bottom-side surface of the semiconductor substrate (or wafer, or body), which still holds and includes at least 1 (or at least 2, or at least 3, or at least 5, or at least 10, or at least 15, or at least 20, or at least 25, or at least 33; but not more than 50, or not more than 40) percent of the entire depth or the entire thickness (or the maximum thickness or depth) of the semiconductor substrate or body or wafer; as those “segments” are still connected at their base through such thin layer, and those “segments” have between them (or among them) the non-transcending gaps or the “blind gaps” or the non-transcending craters that thus separate those “segments” but that do not fully divide or fully break or fully isolate any two such neighboring “segments” from each other. Upon its production, and prior to attaching the solar cells onto the floating medium layer, each such flexible and rollable solar cell is freestanding and carrier-less and non-supported.

In some embodiments, the non-transcending gaps or the “blind gaps” or craters or slits or grooves, are introduced and are formed only at a first side or at a first surface of the semiconductor substrate or body or wafer, and are not formed at both of the opposite surfaces (or sides) thereof.

In some embodiments, the non-transcending gaps or the “blind gaps” or craters or slits or grooves, are introduced and are formed only at a first side or at a first surface of the semiconductor substrate or body or wafer, that is intended to face the sunlight or the light, or that is the active side of the PV device or PV cell, or that is intended to be the active side of the PV device or PV cell, or that is intended to be the electricity-generating side or surface that would generated electricity based on incoming sunlight or light or based on the PV effect; and they are not formed at the other (e.g., opposite, non-active) side or surface (e.g., the side that is not intended to be facing the sunlight or the light, or the side that is not intended to be producing electricity based on the PV effect).

In other embodiments, the non-transcending gaps or the “blind gaps” or craters or slits or grooves, are not introduced and are not formed at the side or surface of the semiconductor substrate or body or wafer, that is intended to face the sunlight or the light, or that is the active side of the PV device or PV cell, or that is intended to be the active side of the PV device or PV cell, or that is intended to be the electricity-generating side or surface that would generated electricity based on incoming sunlight or light or based on the PV effect; but rather, those non-transcending gaps or the “blind gaps” or craters or slits or grooves are formed at the other (e.g., opposite, non-active) side or surface, which is the side that is not intended to be facing the sunlight or the light, or the side that is not intended to be producing electricity based on the PV effect. Some implementations with this structure may advantageously provide the mechanical shock absorption and the mechanical forces dissipation capability, yet may also provide or maintain or achieve an increased level of PV-based electricity production since the gaps do not reduce the area of the light-exposed side or the light-facing side of the PV device.

In still other embodiments, the non-transcending gaps or the “blind gaps” or craters or slits or grooves, are introduced and are formed at both sides or at both surfaces of the semiconductor substrate or body or wafer; yet with an offset among the gaps of the first side and the gaps of the second side, in a zig-zag pattern of those gaps which zig-zag across the two sides of the semiconductor wafer or substrate or body; for example, a first gap located at the top surface on the left; then, a second gap located at the bottom surface to the right side of the first gap and not overlapping at all with the first gap; then, a third gap located at the top surface to the right side of the second gap and not overlapping at all with the second gap; then, a fourth gap located at the bottom surface to the right side of the third gap and not overlapping at all with the third gap; and so forth. In such structure, for example, any single point or any single location or any single region of the remaining semiconductor wafer or substrate or wafer, may have a gap or a crater or a “blind gap” only on one of its two sides, but not on both of its sides.

In yet other embodiments, the non-transcending gaps or the “blind gaps” or craters or slits or grooves, are introduced and are formed at both sides or at both surfaces of the semiconductor substrate or body or wafer; not necessarily with an offset among the gaps of the first side and the gaps of the second side, and not necessarily in a zig-zag pattern; but rather, by implementing any other suitable structure or pattern that still provides the mechanical shock resilience, and while also maintaining a sufficiently-thin layer of semiconductor substrate or body or wafer that is not removed and that is resilient to mechanical shocks and mechanical forces due to the craters or gaps that surround it.

In some embodiments, craters or grooves or trenches or non-transcending gaps may contain, or may be filled (partially, or entirely), with filler material(s) which may include one or more of the following materials: a polymer; a monomer; an oligomer; a resin, amorphous silicon; glass; fiber glass; carbon; a second type of silicon or semiconductor; a reactive system (e.g. monomer and photo-initiator); Ethylene-Vinyl Acetate (EVA); poly (ethylene-vinyl acetate) (PEVA); thermoplastic material; polyvinylidene fluoride (PVDF); Silicone; a homogeneous filler; a heterogeneous filler (for example, formed of a matrix material (e.g. a polymer) and an additive (e.g. discrete domains of a second, softer polymer), or the like); high-impact polystyrene (HIPS); thermoplastic elastomers (TPEs); block copolymers of polystyrene-polybutadiene and/or polystyrene-polyisoprene (diblock, triblock, multiblock, and/or other co-polymers); Polyisoprene or natural rubber; Polychloroprene or neoprene; polybutadiene; ethylene propylene diene monomer (EPDM) rubber or synthetic rubber; carbon fibers; Carbon NanoTubes (CNT); wax; metallic powder(s); nano-particles; nano-fibers; Graphene; foamed polyurethane; sponge particles; material(s) including a blowing agent (e.g., azodicarbonamide) to expand the volume of the material(s) within the trench; anisotropic material(s) or fibers or micro-fibers, being placed or deposited into the trench at a particular pre-defined direction or orientation or alignment relative to the outside surface of the solar cell (e.g., such alignment optionally being performed via an external aligning force field or external magnetic field and/or electric field and/or electro-magnetic field); isotropic material(s) or fibers or micro-fibers; and/or a combination of two or more filler materials.

Some embodiments may include and/or may utilize one or more units, devices, connectors, wires, electrodes, and/or methods which are described in United States patent application publication number US 2016/0308155 A1, which is hereby incorporated by reference in its entirety. For example, some embodiments may include and may utilize an electrode arrangement which is configured to define or create a plurality of electricity collection regions, such that within each of the collection regions, at least two sets of conducting wires are provided such that they are insulated from each other, and the at least two sets of conducting wires are connected either in parallel or in series between the collection regions to thus provide accumulating voltage of charge collection. Some embodiments may include an electric circuit for reading-out or collection or aggregation of the generated electricity, configured as an electrodes arrangement, including conducting wires arranged in the form of nets covering zones of a pre-determined area. The electrodes arrangement may be configured or structured to be stretched (e.g., rolled out) along the surface of the PV cell, and may be formed by at least two sets of conducting wires, and may cover a plurality of collection zones or collection regions.

Within each of the electricity collection zones or electricity aggregation zones, the different conducting wires are insulated from each other, to provide a certain voltage between them. At a transition between zones, the negative charges collecting conductive wire of one zone, is electrically connected to the positive charges collecting conductive wire of the adjacent or the consecutive zone. Thus, within each of the collection zones, the different sets of conducting wires are insulated from each other, while being connected in series between the zones. This configuration of the electrode arrangement allows accumulation or aggregation of electric voltage generated by charge collection along the surface of the PV device. The configuration of the electrode arrangement provides a robust electric collection structure.

The internal connections between the sets of conducting wires allow energy collection even if the surface being covered is not continuous, e.g., if a perforation occurs in the structure of the net. This feature of the electrode arrangement allows for using this technique on any surface exposed to photon radiation, while also allowing discontinuity if needed and without limiting or disrupting the electric charge collection.

In some embodiments, a set of conducting wires may be embedded in or within a flexible and/or adhesive and/or transparent-to-light plastic/polymeric foil or plastic/polymeric film or encapsulant, is embedded immediately beneath such film or foil or encapsulant, or immediately over such film or foil or encapsulant, or is included within such film or foil or encapsulant (e.g., such that the plastic or encapsulant is to the right and to the left of each conducting wire but does not obstruct and does not prevent the conducting wire from touching the solar cell surface for collecting electric charge therefrom). In some embodiments, the sunny-side surface and/or the dark-side surface of each solar cell, or the top-side and/or the bottom-side of each solar cell, may be coated with an adhesive or a transparent adhesive and/or with an electrically-conducting adhesive and/or an electrically-conducting transparent adhesive, to enable gluing or bonding of such surface of the PV cell to the set of conducting wires, for long-term bonding or at least for short-term bonding during the production process before the plastic foil is heated and/or before the PV cell is laminated or encapsulated.

In some embodiments, some, or all, or a majority of, the non-transcending craters or “blind gaps”, are filled with one or more filler material(s), which further provide mechanical shock absorption and/or mechanical shock dissipation and/or thermal resilience and/or mechanical resilience and/or physical resilience and/or chemical resilience and/or mechanical durability and/or thermal durability and/or physical durability and/or chemical durability.

In some embodiments, each of the solar cells in the array, and/or the entirety of the array of solar cells, is laminated and/or encapsulated, within a single lamination layer or a single encapsulation layer, or within two or more layers or coatings or encapsulants, which may be transparent and enable light to pass there-through, or which may be translucent and may enable at least 75% of light to pass there-through, and which may provide further mechanical resilience and damage protection to the solar cells and their array.

In some embodiments, a device comprises a self-floating, rollable, flexible, photovoltaic article, that is formed of a plurality of flexible and rollable and mechanically-resilient solar cells that are inter-connected as a generally planar (yet flexible and rollable) array. Each of said flexible and rollable and mechanically-resilient solar cells has (I) a sunny-side or top-side surface that is configured to absorb light, and (II) a back-side or bottom-side surface that is opposite to said sunny-side surface and is not necessarily configured to absorb light (e.g., in some implementations it does not absorb light and it is a “dark side”; or, in other implementations, it also absorbs light and it is a “sunny side”). Each of said flexible and rollable and mechanically-resilient solar cells is configured to generate electric current from light via the photovoltaic effect.

Some embodiments provide a flexible Photovoltaic (PV) device, comprising: a flexible PV cell, configured to generate electricity from light; a stretchable and compressible Patterned Metal Wiring Mesh, that is attached to a surface of said flexible PV cell, and that is configured to collect and aggregate PV-generated electricity from said flexible PV cell; wherein the stretchable and compressible Patterned Metal Wiring Mesh is capable of stretching or compressing in response to mechanical forces that are applied to said flexible PV cell, while generally maintaining physical connectivity and electrical connectivity to electricity-generating regions of said PV cell.

In some embodiments, the stretchable and compressible Patterned Metal Wiring Mesh is configured, by having a pre-defined layout of patterned metal wires, to withstand mechanical shocks that are applied to said flexible PV cell.

In some embodiments, the stretchable and compressible Patterned Metal Wiring Mesh has a pre-defined layout of knitted metal wires that are knitted and/or woven and/or looped with each other; wherein said pre-defined layout provides to said Patterned Metal Wiring Mesh a capability to dynamically stretch or dynamically compress in response to mechanical forces while generally maintaining physical connectivity and electrical connectivity to electricity-generating regions of said flexible PV cell.

In some embodiments, the stretchable and compressible Patterned Metal Wiring Mesh has a pre-defined layout of zig-zag metal wires; wherein said pre-defined layout provides to said Patterned Metal Wiring Mesh a capability to dynamically stretch or dynamically compress in response to mechanical forces while generally maintaining physical connectivity and electrical connectivity to electricity-generating regions of said flexible PV cell.

In some embodiments, the stretchable and compressible Patterned Metal Wiring Mesh has a pre-defined layout of sinusoid or wavy metal wires; wherein said pre-defined layout provides to said Patterned Metal Wiring Mesh a capability to dynamically stretch or dynamically compress in response to mechanical forces while generally maintaining physical connectivity and electrical connectivity to electricity-generating regions of said flexible PV cell.

In some embodiments, at least some wire segments of said stretchable and compressible Patterned Metal Wiring Mesh are capable of expanding their length or increasing their curvature in response to mechanical forces that are applied to said flexible PV cell, while maintaining physical connection and electrical connection to electricity-generating regions of said flexible PV cell.

In some embodiments, at least some wire segments of said stretchable and compressible Patterned Metal Wiring Mesh are capable of shortening their length or decreasing their curvature in response to mechanical forces that are applied to said flexible PV cell, while maintaining physical connection and electrical connection to electricity-generating regions of said flexible PV cell.

In some embodiments, the stretchable and compressible Patterned Metal Wiring Mesh is a thin metal sheet that is intentionally wrinkled and non-smooth, and has a three-dimensional layout of crumples and wrinkles on its surface that touches the flexible PV device; wherein said three-dimensional layout of crumples and wrinkles on said surface of said metal sheet, provides to said Patterned Metal Wiring Mesh a capability to dynamically stretch or dynamically compress in response to mechanical forces while generally maintaining physical connectivity and electrical connectivity to electricity-generating regions of said flexible PV cell.

In some embodiments, the stretchable and compressible metal Patterned Metal Wiring Mesh further connects, mechanically and electrically, two or more neighboring and flexible solar cell, which together form a flexible solar module.

In some embodiments, the stretchable and compressible Patterned Metal Wiring Mesh is formed of one or more of: tin, aluminum, copper, silver, copper covered or coated by tin, a single metal, an alloy of two or more metals, a combination of two or more metals.

In some embodiments, the stretchable and compressible Patterned Metal Wiring Mesh is non-detachably embedded onto a Flexible Polymeric Support Foil, which supports both (i) the stretchable and compressible Patterned Metal Wiring Mesh and (ii) the flexible PV cell.

In some embodiments, the stretchable and compressible Patterned Metal Wiring Mesh is non-detachably embedded at least partially within a Flexible Polymeric Support Foil, which supports both (i) the stretchable and compressible Patterned Metal Wiring Mesh and (ii) the flexible PV cell.

In some embodiments, the stretchable and compressible Patterned Metal Wiring Mesh foil is non-detachably attached to a surface of said flexible PV cell that is penetrated, partially but not entirely, by non-transcending trenches that penetrate into between 50 to 99 percent of a total depth of a silicon bulk of said flexible PV cell; wherein said non-transcending trenches provide flexibility and mechanical resilience to said flexible PV cell.

In some embodiments, the stretchable and compressible Patterned Metal Wiring Mesh is non-detachably attached to a first surface of said flexible PV cell, that is opposite to a second surface of that PV cell which is penetrated, partially but not entirely, by non-transcending trenches that penetrate into between 50 to 99 percent of a total depth of a silicon bulk of said flexible PV cell; wherein said non-transcending trenches provide flexibility and mechanical resilience to said flexible PV cell. In some embodiments, optionally, said non-transcending trenches (or some of them, or most of them, or all of them) are filled, partially or entirely, with one or more filler materials that provide additional flexibility and additional mechanical resilience to said flexible PV cell.

In some embodiments, optionally, the stretchable and compressible Patterned Metal Wiring Mesh have wire segments that are non-flat, and is a non-planar mesh and is a non-planar network of metal wires, and has three-dimensionally protruding regions or curves or curls or waves or ribs; that three-dimensionally protrude away from the Flexible Polymeric Support Foil, in an idle state (e.g., non-folded, non-rolled, non-flexed, generally planar) of the Flexible Polymeric Support Foil and/or of the PV cell or PV device; and such three-dimensional structure enables those segments of the Patterned Metal Wiring Mesh to stretch and to compress in response to mechanical forces as the Flexible Polymeric Support Foil (and the attached PV device) is folded or rolled or curved or flexed, while also maintaining electrical conductivity and connectivity to collect and transport the PV-generated electricity from the electricity-generating regions of the PV device.

In some embodiments, a method of producing a flexible Photovoltaic (PV) device comprises: producing a flexible PV cell, configured to generate electricity from light; producing a stretchable and compressible Patterned Metal Wiring Mesh, and attaching it to a surface of said flexible PV cell; wherein the stretchable and compressible Patterned Metal Wiring Mesh is configured to collect and aggregate PV-generated electricity from said flexible PV cell; wherein the stretchable and compressible Patterned Metal Wiring Mesh is capable of stretching or compressing in response to mechanical forces that are applied to said flexible PV cell, while generally maintaining physical connectivity and electrical connectivity to electricity-generating regions of said PV cell.

In some embodiments, producing the stretchable and compressible Patterned Metal Wiring Mesh comprises: non-detachably embedding said stretchable and compressible Patterned Metal Wiring Mesh onto a Flexible Polymeric Support Foil, which supports both (i) the stretchable and compressible Patterned Metal Wiring Mesh and (ii) the flexible PV cell.

In some embodiments, producing the stretchable and compressible Patterned Metal Wiring Mesh comprises: non-detachably embedding said stretchable and compressible Patterned Metal Wiring Mesh at least partially into a Flexible Polymeric Support Foil, which supports both (i) the stretchable and compressible Patterned Metal Wiring Mesh and (ii) the flexible PV cell.

The terms “plurality” and “a plurality”, as used herein, include, for example, “multiple” or “two or more”. For example, “a plurality of items” includes two or more items.

References to “one embodiment”, “an embodiment”, “demonstrative embodiment”, “various embodiments”, “some embodiments”, and/or similar terms, may indicate that the embodiment(s) so described may optionally include a particular feature, structure, or characteristic, but not every embodiment necessarily includes the particular feature, structure, or characteristic. Furthermore, repeated use of the phrase “in one embodiment” does not necessarily refer to the same embodiment, although it may Similarly, repeated use of the phrase “in some embodiments” does not necessarily refer to the same set or group of embodiments, although it may

As used herein, and unless otherwise specified, the utilization of ordinal adjectives such as “first”, “second”, “third”, “fourth”, and so forth, to describe an item or an object, merely indicates that different instances of such like items or objects are being referred to; and does not intend to imply as if the items or objects so described must be in a particular given sequence, either temporally, spatially, in ranking, or in any other ordering manner.

Functions, operations, components and/or features described herein with reference to one or more embodiments, may be combined with, or may be utilized in combination with, one or more other functions, operations, components and/or features described herein with reference to one or more other embodiments. Some embodiments may thus comprise any possible or suitable combinations, re-arrangements, assembly, re-assembly, or other utilization of some or all of the modules or functions or components that are described herein, even if they are discussed in different locations or different chapters of the above discussion, or even if they are shown across different drawings or multiple drawings.

While certain features of some demonstrative embodiments have been illustrated and described herein, various modifications, substitutions, changes, and equivalents may occur to those skilled in the art. Accordingly, the claims are intended to cover all such modifications, substitutions, changes, and equivalents.

What is claimed is:

1. A flexible Photovoltaic (PV) device, comprising:
a flexible PV cell, configured to generate electricity from light;
a stretchable and compressible Patterned Metal Wiring Mesh, that is attached to a surface of said flexible PV cell, and that is configured to collect and aggregate PV-generated electricity from said flexible PV cell;
wherein the stretchable and compressible Patterned Metal Wiring Mesh is capable of stretching or compressing in response to mechanical forces that are applied to said flexible PV cell, while generally maintaining physical connectivity and electrical connectivity to electricity-generating regions of said PV cell.

2. The flexible PV device according to claim 1,
wherein the stretchable and compressible Patterned Metal Wiring Mesh is configured, by having a pre-defined layout of patterned metal wires, to withstand mechanical shocks that are applied to said flexible PV cell.

3. The flexible PV device according to claim 2,
wherein the stretchable and compressible Patterned Metal Wiring Mesh has a pre-defined layout of knitted metal wires that are knitted and/or woven and/or looped with each other;
wherein said pre-defined layout provides to said Patterned Metal Wiring Mesh a capability to dynamically stretch or dynamically compress in response to mechanical forces while generally maintaining physical connectivity and electrical connectivity to electricity-generating regions of said flexible PV cell.

4. The flexible PV device according to claim 3,
wherein the stretchable and compressible Patterned Metal Wiring Mesh has a pre-defined layout of zig-zag metal wires;
wherein said pre-defined layout provides to said Patterned Metal Wiring Mesh a capability to dynamically stretch or dynamically compress in response to mechanical forces while generally maintaining physical connectivity and electrical connectivity to electricity-generating regions of said flexible PV cell.

5. The flexible PV device according to claim 3,
wherein the stretchable and compressible Patterned Metal Wiring Mesh has a pre-defined layout of sinusoid or wavy metal wires;
wherein said pre-defined layout provides to said Patterned Metal Wiring Mesh a capability to dynamically stretch or dynamically compress in response to mechanical forces while generally maintaining physical connectivity and electrical connectivity to electricity-generating regions of said flexible PV cell.

6. The flexible PV device according to claim 3,
wherein at least some wire segments of said stretchable and compressible Patterned Metal Wiring Mesh are capable of expanding their length or increasing their curvature in response to mechanical forces that are applied to said flexible PV cell, while maintaining physical connection and electrical connection to electricity-generating regions of said flexible PV cell.

7. The flexible PV device according to claim 6,
wherein at least some wire segments of said stretchable and compressible Patterned Metal Wiring Mesh are capable of shortening their length or decreasing their curvature in response to mechanical forces that are applied to said flexible PV cell, while maintaining physical connection and electrical connection to electricity-generating regions of said flexible PV cell.

8. The flexible PV device according to claim 1,
wherein the stretchable and compressible Patterned Metal Wiring Mesh is a thin metal sheet that is intentionally wrinkled and non-smooth, and has a three-dimensional layout of crumples and wrinkles on its surface that touches the flexible PV device;
wherein said three-dimensional layout of crumples and wrinkles on said surface of said metal sheet, provides to said Patterned Metal Wiring Mesh a capability to dynamically stretch or dynamically compress in response to mechanical forces while generally maintaining physical connectivity and electrical connectivity to electricity-generating regions of said flexible PV cell.

9. The flexible PV device according to claim 8,
wherein the stretchable and compressible metal Patterned Metal Wiring Mesh further connects, mechanically and electrically, two or more neighboring and flexible solar cells, which together form a flexible solar module.

10. The flexible PV device according to claim 8,
wherein the stretchable and compressible Patterned Metal Wiring Mesh is formed of one or more of:
tin, aluminum, copper, silver,
copper covered or coated by tin,
a single metal,
an alloy of two or more metals,
a combination of two or more metals.

11. The flexible PV device according to claim 1,
wherein the stretchable and compressible Patterned Metal Wiring Mesh is non-detachably embedded onto a Flexible Polymeric Support Foil, which supports both (i) the stretchable and compressible Patterned Metal Wiring Mesh and (ii) the flexible PV cell.

12. The flexible PV device according to claim 1,
wherein the stretchable and compressible Patterned Metal Wiring Mesh is non-detachably embedded at least partially within a Flexible Polymeric Support Foil, which supports both (i) the stretchable and compressible Patterned Metal Wiring Mesh and (ii) the flexible PV cell.

13. The flexible PV device according to claim 1,
wherein the stretchable and compressible Patterned Metal Wiring Mesh foil is non-detachably attached to a surface of said flexible PV cell that is penetrated, partially but not entirely, by non-transcending trenches that penetrate into between 50 to 99 percent of a total depth of a silicon bulk of said flexible PV cell; wherein said non-transcending trenches provide flexibility and mechanical resilience to said flexible PV cell.

14. The flexible PV device according to claim 13,
wherein said non-transcending trenches are filled, partially or entirely, with one or more filler materials that provide additional flexibility and additional mechanical resilience to said flexible PV cell.

15. The flexible PV device according to claim 1,
wherein the stretchable and compressible Patterned Metal Wiring Mesh is non-detachably attached to a first surface of said flexible PV cell, that is opposite to a second surface of that PV cell which is penetrated, partially but not entirely, by non-transcending trenches that penetrate into between 50 to 99 percent of a total depth of a silicon bulk of said flexible PV cell; wherein said non-transcending trenches provide flexibility and mechanical resilience to said flexible PV cell.

16. The flexible PV device according to claim 15,
wherein said non-transcending trenches are filled, partially or entirely, with one or more filler materials that provide additional flexibility and additional mechanical resilience to said flexible PV cell.

17. A method of producing a flexible Photovoltaic (PV) device, the method comprising:
producing a flexible PV cell, configured to generate electricity from light;
producing a stretchable and compressible Patterned Metal Wiring Mesh, and attaching it to a surface of said flexible PV cell; wherein the stretchable and compressible Patterned Metal Wiring Mesh is configured to collect and aggregate PV-generated electricity from said flexible PV cell;
wherein the stretchable and compressible Patterned Metal Wiring Mesh is capable of stretching or compressing in response to mechanical forces that are applied to said flexible PV cell, while generally maintaining physical connectivity and electrical connectivity to electricity-generating regions of said PV cell.

18. The method of claim 17,
wherein producing the stretchable and compressible Patterned Metal Wiring Mesh comprises:
non-detachably embedding said stretchable and compressible Patterned Metal Wiring Mesh onto a Flexible Polymeric Support Foil, which supports both (i) the stretchable and compressible Patterned Metal Wiring Mesh and (ii) the flexible PV cell.

19. The method of claim 17,
wherein producing the stretchable and compressible Patterned Metal Wiring Mesh comprises:
non-detachably embedding said stretchable and compressible Patterned Metal Wiring Mesh at least partially into a Flexible Polymeric Support Foil, which supports both (i) the stretchable and compressible Patterned Metal Wiring Mesh and (ii) the flexible PV cell.

20. The method of claim 17, comprising:
non-detachably attaching the stretchable and compressible Patterned Metal Wiring Mesh, to a particular surface of said PV cell which is penetrated, partially but not entirely, by non-transcending trenches that penetrate into between 50 to 99 percent of a total depth of a silicon bulk of said flexible PV cell; wherein said non-transcending trenches provide flexibility and mechanical resilience to said flexible PV cell;
filling said non-transcending trenches, partially or entirely, with one or more filler materials that provide additional flexibility and additional mechanical resilience to said flexible PV cell.
